(19) United States
(12) Patent Application Publication
(10) Pub. No.: US 2013/0119406 A1
(43) Pub. Date: May 16, 2013

(54) SILICON CARBIDE SUBSTRATE, SEMICONDUCTOR DEVICE, AND METHODS FOR MANUFACTURING THEM

(71) Applicants: Hiroshi NOTSU, Osaka-shi (JP); Shin Harada, Osaka-shi (JP); Keiji Ishibashi, Itami-shi (JP); Tsutomu Hori, Itami-shi (JP); Yu Saitoh, Osaka-shi (JP)

(72) Inventors: Hiroshi NOTSU, Osaka-shi (JP); Shin Harada, Osaka-shi (JP); Keiji Ishibashi, Itami-shi (JP); Tsutomu Hori, Itami-shi (JP); Yu Saitoh, Osaka-shi (JP)

(73) Assignee: SUMITOMO ELECTRIC INDUSTRIES, LTD., Osaka-shi (JP)

(21) Appl. No.: 13/613,860

(22) Filed: Sep. 13, 2012

Related U.S. Application Data
(60) Provisional application No. 61/559,483, filed on Nov. 14, 2011.

(30) Foreign Application Priority Data
Nov. 14, 2011 (JP) 2011-248312

(51) Int. Cl. H01L 29/24; H01L 21/20

(52) U.S. Cl. 257/77; 438/478; 438/483; 438/488; 257/E29.104; 257/E21.09

(57) ABSTRACT

A silicon carbide substrate includes a base layer made of silicon carbide, silicon carbide layers made of single-crystal silicon carbide and arranged side by side on the base layer when viewed in plan view, and a filling portion made of silicon carbide and filling a gap formed between the adjacent silicon carbide layers. The filling portion has a surface roughness of not more than 50 μm in RMS value.

### BACKGROUND OF THE INVENTION

1. Field of the Invention

The present invention relates to a silicon carbide substrate, a semiconductor device, and methods for manufacturing them, and more particularly to a silicon carbide substrate on which a high quality epitaxially grown layer can be formed, a semiconductor device including the silicon carbide substrate, and methods for manufacturing them.

2. Description of the Background Art

In recent years, silicon carbide has been increasingly employed as a material for a semiconductor device in order to attain a higher breakdown voltage, lower loss and the like of the semiconductor device. Silicon carbide is a wide band gap semiconductor having a band gap wider than that of silicon which has been conventionally and widely used as a material for a semiconductor device. By employing silicon carbide as a material for a semiconductor device, therefore, a higher breakdown voltage, lower on-resistance and the like of the semiconductor device can be achieved. A semiconductor device made of silicon carbide also has the advantage of exhibiting less performance degradation when used in a high-temperature environment than a semiconductor device made of silicon.

In order to efficiently manufacture a semiconductor device, it is effective to use a large-diameter substrate. Accordingly, various studies have been conducted on silicon carbide substrates made of single-crystal silicon carbide and having a diameter of 3 inches or 4 inches as well as methods for manufacturing them. For example, methods for manufacturing a silicon carbide substrate by sublimation have been proposed.

In order to fabricate a large-diameter silicon carbide substrate by sublimation, temperature needs to be uniform in a large area thereof. However, since the growth temperature of silicon carbide in sublimation is as high as not less than 2000° C., it is difficult to control the temperature, and hence it is not easy to have a large area of uniform temperature. Furthermore, in the fabrication of a silicon carbide substrate by sublimation, it is difficult to check a crystal growth process of silicon carbide. Even when the crystal growth of silicon carbide is done under the externally same conditions, substrates (crystals) obtained may be disadvantageously different from each other in quality. As such, even with the sublimation that relatively readily allows for a large diameter, it is difficult to fabricate a large-diameter silicon carbide substrate having excellent crystallinity.

To address this problem, it has been proposed to arrange a plurality of small-diameter SiC substrates having excellent crystallinity side by side in plan view, and form a large-diameter base substrate supporting these SiC substrates, for example, to handle these SiC substrates as a large-diameter silicon carbide substrate having excellent crystallinity (see WO 2011/052321 (Patent Literature 1), for example).

According to the method for manufacturing a silicon carbide substrate proposed in Patent Literature 1, the small-diameter SiC substrates having excellent crystallinity and the large-diameter base substrate are joined to each other by close-spaced sublimation and the like, thereby obtaining a silicon carbide substrate that can be handled as a large-diameter substrate. While this method allows for a sufficient degree of adhesion between the SiC substrates and the base substrate, when gaps between the adjacent SiC substrates are filled, a filling failure such as a reduction in filling ratio in the gaps and a deterioration in surface roughness of the filling portions may occur. If an epitaxially grown layer is formed on such silicon carbide substrate, an abnormally grown crystal such as a needle-like projection is formed due to the filling failure. Such needle-like projection readily breaks and acts as a source of particles during subsequent manufacturing steps of a semiconductor device, causing a reduction in quality such as electrical characteristics and durability of the semiconductor device.

### SUMMARY OF THE INVENTION

The present invention was made in view of the above problems, and an object of the present invention is to provide a silicon carbide substrate on which a high quality epitaxially grown layer can be formed, a semiconductor device including the silicon carbide substrate, and methods for manufacturing them.

A silicon carbide substrate according to the present invention includes a base layer made of silicon carbide, silicon carbide layers made of single-crystal silicon carbide and arranged side by side on the base layer when viewed in plan view, and a filling portion made of silicon carbide and filling a gap formed between the adjacent silicon carbide layers. The filling portion has a surface roughness of not more than 50 μm in RMS value.

In the silicon carbide substrate according to the present invention, the filling portion filling the gap formed between the adjacent silicon carbide layers has a surface roughness reduced to not more than 50 μm in RMS value. When forming an epitaxially grown layer on a surface of the silicon carbide substrate according to the present invention, therefore, the formation of abnormally grown crystal can be suppressed, thereby suppressing the generation of particles which would be produced by the breakage of such crystal. Thus, according to the silicon carbide substrate of the present invention, a silicon carbide substrate on which a high quality epitaxially grown layer can be formed can be provided.

In the silicon carbide substrate, the filling portion may have a surface roughness of not less than 0.1 μm in RMS value.

When the filling portion has a surface roughness of not more than 0.1 μm in RMS value, a pronounced effect of reduced surface roughness of the filling portion on an yield of the semiconductor device including the silicon carbide substrate cannot be obtained. Thus, by setting the surface roughness of the filling portion to not less than 0.1 μm in RMS value, cost reduction and productivity improvement in the manufacture of the silicon carbide substrate can be realized while a high quality epitaxially grown layer can be formed.

In the silicon carbide substrate, the silicon carbide layers may have a surface roughness of not more than 0.5 nm in RMS value. As a result, a high quality epitaxially grown layer can be formed more readily on the silicon carbide substrate.

In the silicon carbide substrate, the silicon carbide layers may have a dislocation density of not less than 1×10³ cm⁻² and not more than 2×10⁴ cm⁻². As a result, the yield of the semiconductor device including the silicon carbide substrate can be increased.

In the silicon carbide substrate, the silicon carbide layers may have a carrier concentration of not less than 2×10¹⁸ cm⁻³ and not more than 2×10¹⁹ cm⁻³. As a result, a good on-resistance can be achieved in the semiconductor device including the silicon carbide substrate.

The silicon carbide substrate may have a diameter of not less than 110 mm. By using such large-diameter silicon carbide substrate, cost reduction and efficiency improvement in the manufacture of the semiconductor device can be realized.

In the silicon carbide substrate, each of the plurality of silicon carbide layers may be made of hexagonal silicon carbide. A surface of each of the plurality of silicon carbide layers, which forms a main surface opposite to the base layer, may have an off angle of not less than 0.10 and not more than 10° relative to a {0001} plane. As a result, the epitaxially grown layer can be readily formed on the silicon carbide substrate.

In the silicon carbide substrate, each of the plurality of silicon carbide layers may be made of hexagonal silicon carbide. A surface of each of the plurality of silicon carbide layers, which forms a main surface opposite to the base layer, may have an off angle of not more than 4° relative to a {03-38} plane. As a result, a good channel mobility can be achieved in the semiconductor device including the silicon carbide substrate.

In the silicon carbide substrate, the number of metal atoms per 1 cm² present on a main surface on which the silicon carbide layers are arranged may be not more than 1×10¹⁵. As a result, a high quality epitaxially grown layer can be formed more readily on the silicon carbide substrate.

In the silicon carbide substrate, the number of Na atoms per 1 cm² present on the main surface on which the silicon carbide layers are arranged may be not more than 1×10¹⁴. As a result, a high quality epitaxially grown layer can be formed more readily on the silicon carbide substrate.

A semiconductor device according to the present invention includes a substrate, and an electrode formed on the substrate. The substrate is the silicon carbide substrate according to the present invention.

The semiconductor device according to the present invention includes the silicon carbide substrate according to the present invention, on which a high quality epitaxially grown layer can be formed. According to the semiconductor device of the present invention, therefore, a high quality semiconductor device can be provided.

The semiconductor device may further include an epitaxially grown layer formed on the substrate. The electrode may be formed on the epitaxially grown layer.

As a result, the semiconductor device including the electrode formed on the high quality epitaxially grown layer can be readily manufactured.

A method for manufacturing a silicon carbide substrate according to one aspect of the present invention includes the steps of preparing a composite substrate, in which a plurality of silicon carbide layers made of single-crystal silicon carbide and arranged side by side when viewed in plan view are held on a base layer made of silicon carbide, removing a surface layer portion of the base layer exposed between the adjacent silicon carbide layers, and after the step of removing a surface layer portion of the base layer, forming a filling portion made of silicon carbide and filling a gap between the adjacent silicon carbide layers.

A method for manufacturing a silicon carbide substrate according to another aspect of the present invention includes the steps of preparing a composite substrate, in which a plurality of silicon carbide layers made of single-crystal silicon carbide and arranged side by side when viewed in plan view are held on a base layer made of silicon carbide, forming a cover layer covering a surface of the base layer exposed between the adjacent silicon carbide layers, and after the step of forming a cover layer covering a surface of the base layer, forming a filling portion made of silicon carbide and filling a gap between the adjacent silicon carbide layers.

The present inventors studied in detail the cause of a reduction in filling ratio in the gap between the adjacent silicon carbide layers and a deterioration in surface roughness of the filling portion. As a result, it was found that the cause was a large surface roughness of the base layer exposed between the adjacent silicon carbide layers.

In the method for manufacturing a silicon carbide substrate according to the one aspect of the present invention, before the filling portion is formed, the surface roughness of the base layer is reduced by removing the surface layer portion of the base layer exposed between the adjacent silicon carbide layers. In the method for manufacturing a silicon carbide substrate according to the another aspect of the present invention, before the filling portion is formed, the surface roughness of the base layer is reduced by forming the cover layer covering the surface of the base layer exposed between the adjacent silicon carbide layers. In this manner, according to the methods for manufacturing a silicon carbide substrate of the present invention, the surface roughness of the base layer exposed between the adjacent silicon carbide layers is reduced before the filling portion is formed, thereby manufacturing a silicon carbide substrate in which a reduction in filling ratio in the gap between the silicon carbide layers and a deterioration in surface roughness of the filling portions are suppressed. Accordingly, when forming an epitaxially grown layer on the silicon carbide substrate, the abnormal crystal growth or the like caused by a reduction in filling ratio in the gap between the silicon carbide layers and a deterioration in surface roughness of the filling portion is suppressed, thereby suppressing the generation of particles that would cause a reduction in quality such as electrical characteristics and durability of the semiconductor device. According to the methods for manufacturing a silicon carbide substrate of the present invention, therefore, a silicon carbide substrate on which a high quality epitaxially grown layer can be formed can be manufactured.

In the method for manufacturing a silicon carbide substrate according to the one aspect, in the step of removing a surface layer portion of the base layer, the surface layer portion of the base layer may be removed such that the base layer exposed between the adjacent silicon carbide layers has a surface roughness of not more than 0.5 μm in RMS value.

As a result, a reduction in filling ratio in the gap between the adjacent silicon carbide layers and a deterioration in surface roughness of the filling portion can be suppressed more effectively.

In the method for manufacturing a silicon carbide substrate according to the another aspect, in the step of forming a cover layer, the cover layer made of silicon carbide may be formed.

By forming the cover layer made of silicon carbide in this manner, a silicon carbide substrate on which a high quality epitaxially grown layer can be formed can be manufactured more readily.

In the method for manufacturing a silicon carbide substrate according to the another aspect, in the step of forming a cover layer, the cover layer made of amorphous or polycrystalline silicon carbide may be formed.

As a result, the cover layer made of silicon carbide and covering the surface of the base layer exposed between the adjacent silicon carbide layers can be formed more readily.

In the method for manufacturing a silicon carbide substrate according to the another aspect, the step of forming a cover layer may include the steps of forming a precursor layer including an organic material made of Si and C and covering the surface of the base layer exposed between the adjacent silicon carbide layers, and forming the cover layer made of silicon carbide by sintering the precursor layer.

As a result, the cover layer made of silicon carbide and covering the surface of the base layer exposed between the adjacent silicon carbide layers can be formed more readily.

In the method for manufacturing a silicon carbide substrate according to the another aspect, in the step of forming a cover layer, the cover layer may be formed by CVD.

As a result, the cover layer made of silicon carbide and covering the surface of the base layer exposed between the adjacent silicon carbide layers can be formed further readily.

In the method for manufacturing a silicon carbide substrate according to the another aspect, in the step of forming a cover layer, the cover layer may be formed to have a surface roughness of not more than 0.3 μm in RMS value.

As a result, a reduction in filling ratio in the gap between the silicon carbide layers and a deterioration in surface roughness of the filling portion can be suppressed further effectively.

A method for manufacturing a semiconductor device according to one aspect of the present invention includes the steps of preparing a substrate, and forming an electrode on the substrate. In the step of preparing a substrate, the silicon carbide substrate manufactured with the method for manufacturing a silicon carbide substrate according to the present invention is prepared.

A method for manufacturing a semiconductor device according to another aspect of the present invention includes the steps of preparing a substrate, and forming an electrode on the substrate. In the step of preparing a substrate, the silicon carbide substrate according to the present invention is prepared.

In the method for manufacturing a semiconductor device according to the one aspect of the present invention, the silicon carbide substrate on which a high quality epitaxially grown layer can be formed, which is manufactured with the method for manufacturing a silicon carbide substrate according to the present invention, is prepared. Furthermore, in the method for manufacturing a semiconductor device according to the another aspect of the present invention, the silicon carbide substrate according to the present invention on which a higher quality epitaxially grown layer can be formed is prepared. According to the methods for manufacturing a semiconductor device of the present invention, therefore, a high quality semiconductor device can be manufactured by forming a high quality epitaxially grown layer.

The method for manufacturing a semiconductor device may further include the step of forming an epitaxially grown layer on the substrate. In the step of forming an electrode, the electrode may be formed on the epitaxially grown layer.

As a result, the semiconductor device having the electrode formed on the high quality epitaxially grown layer can be readily manufactured.

As is clear from the description above, according to the silicon carbide substrate, the semiconductor device, and the methods for manufacturing them of the present invention, a silicon carbide substrate on which a high quality epitaxially grown layer can be formed, a semiconductor device including the silicon carbide substrate, and methods for manufacturing them can be provided.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross sectional view showing the structure of a MOSFET.

FIG. 2 is a schematic cross sectional view showing the structure of a silicon carbide substrate.

FIG. 3 is a flowchart schematically illustrating a method for manufacturing the MOSFET and the silicon carbide substrate.

FIG. 4 is a schematic cross sectional view for explaining the method for manufacturing the silicon carbide substrate.

FIG. 5 is a schematic cross sectional view for explaining the method for manufacturing the silicon carbide substrate.

FIG. 6 is a schematic cross sectional view for explaining the method for manufacturing the silicon carbide substrate.

FIG. 7 is a schematic cross sectional view for explaining the method for manufacturing the silicon carbide substrate.

FIG. 8 is a schematic cross sectional view for explaining the method for manufacturing the silicon carbide substrate.

FIG. 9 is a schematic cross sectional view for explaining the method for manufacturing the silicon carbide substrate.

FIG. 10 is a schematic cross sectional view for explaining the method for manufacturing the MOSFET.

FIG. 11 is a schematic cross sectional view for explaining the method for manufacturing the MOSFET.

FIG. 12 is a schematic cross sectional view for explaining the method for manufacturing the MOSFET.

FIG. 13 is a flowchart schematically illustrating a method for manufacturing a silicon carbide substrate in a second embodiment.

FIG. 14 is a schematic cross sectional view for explaining the method for manufacturing the silicon carbide substrate in the second embodiment.

FIG. 15 is a schematic cross sectional view for explaining the method for manufacturing the silicon carbide substrate in the second embodiment.

FIG. 16 is a flowchart schematically illustrating a method for manufacturing a silicon carbide substrate in a third embodiment.

### DESCRIPTION OF THE PREFERRED EMBODIMENTS

Embodiments of the present invention will be described with reference to the drawings. It is noted that the same or corresponding parts are designated by the same reference numerals in the following drawings, to avoid repeated description. In the present specification, an individual orientation is indicated with [ ], a group orientation is indicated with < >, an individual plane is indicated with ( ), and a group plane is indicated with { }. Although “-” (bar) is supposed to be attached atop a numeral of an negative index in terms of crystallography, a negative sign is attached before a numeral in the present specification.

### First Embodiment

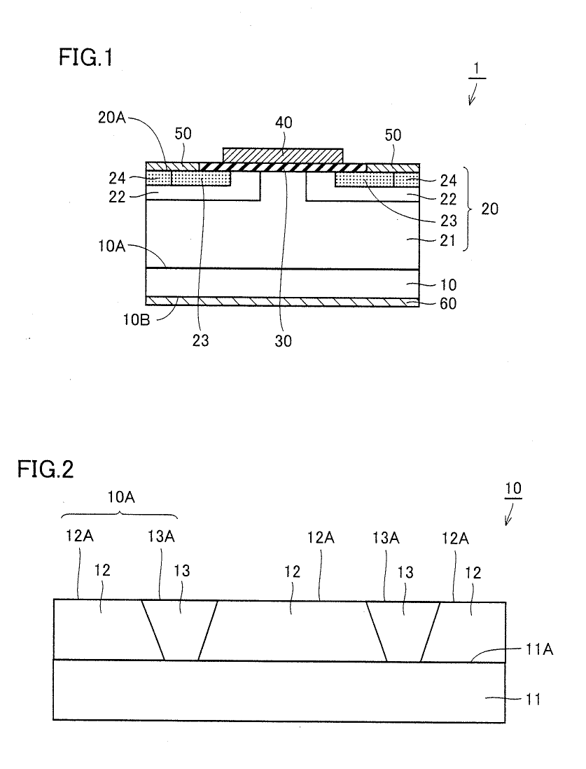

A silicon carbide substrate, a semiconductor device, and methods for manufacturing them in a first embodiment as one embodiment of the present invention will be described first. The structures of the silicon carbide substrate and the semiconductor device in this embodiment will be described first with reference to FIGS. 1 and 2. Referring to FIG. 1, a MOSFET 1 as the semiconductor device in this embodiment includes a silicon carbide substrate 10, a semiconductor layer 20 as an epitaxially grown layer, an oxide film 30, a gate electrode 40, source electrodes 50, and a drain electrode 60. Semiconductor layer 20 has a drift region 21, body regions 22, source regions 23, and contract regions 24 formed therein. Silicon carbide substrate is a silicon carbide substrate in this embodiment.

Referring to FIG. 2, silicon carbide substrate 10 includes a base layer 11 made of silicon carbide, a plurality of silicon carbide layers 12 made of single-crystal silicon carbide, and filling portions 13 made of silicon carbide. The plurality of silicon carbide layers 12 are arranged side by side on a main surface 11A of base layer 11 such that gaps are formed between them when viewed in plan view. Filling portions 13 are formed to fill the gaps between adjacent silicon carbide layers 12. A main surface 13A of each filling portion 13 has a surface roughness of not more than 50 μm in RMS value.

Referring to FIG. 1, drift region 21 is formed on one main surface of silicon carbide substrate 10. Drift region 21 has an n conductivity type by containing an n type impurity such as N (nitrogen).

Body regions 22 are formed to include a main surface 20A of semiconductor layer 20, in drift region 21 opposite to silicon carbide substrate 10. Body regions 22 have a p conductivity type by containing a p type impurity such as Al (aluminum) or B (boron).

Source regions 23 are formed to include main surface 20A and to be in contact with body regions 22. Source regions 23 have an n conductivity type as with drift region 21 by containing an n type impurity such as P (phosphorus), and have a concentration higher than that in drift region 21.

Contact regions 24 are formed to include main surface 20A and to be in contact with body regions 22 and source regions 23. Contact regions 24 have a p conductivity type as with body regions 22 by containing a p type impurity such as Al (aluminum) or B (boron), and have a concentration higher than that in body regions 22.

Oxide film 30 is made of SiO₂ (silicon dioxide), for example, and is formed to partially cover main surface 20A.

Gate electrode 40 is made of a conductor such as polysilicon including an impurity, or Al, and is formed on and in contact with oxide film 30. More specifically, gate electrode 40 is formed to extend from one of source regions 23 to the other source region 23 facing each other under gate electrode 40.

Source electrodes 50 are formed on main surface 20A to be in contact with source regions 23 and contact regions 24. Source electrodes 50 are made of a material capable of making ohmic contact with source regions 23, such as NiₓSi_{y} (nickel silicide), TiₓSi_{y} (titanium silicide), AlₓSi_{y} (aluminum silicide), and TiₓAl_{y}Si_{z} (titanium aluminum silicide), and are electrically connected to source regions 23.

Drain electrode 60 is formed in contact with a main surface of silicon carbide substrate 10 opposite to drift region 21. Drain electrode 60 is made of the same material as that for source electrodes 50, for example, and is electrically connected to silicon carbide substrate 10.

Next, operation of MOSFET 1 as the semiconductor device in this embodiment will be described. Referring to FIG. 1, when a voltage lower than a threshold voltage is applied to gate electrode 40, i.e., in an off state, even if a voltage is applied between source electrodes 50 and drain electrode 60, a pn junction formed between each of body regions 22 and drift region 21 is reverse biased, resulting in a non-conducting state. On the other hand, when a voltage equal to or higher than the threshold voltage is applied to gate electrode 40, an inversion layer is formed in a channel region in each of body regions 22 (body regions 22 under gate electrode 40). As a result, source regions 23 and drift layer 21 are electrically connected to each other, causing a current to flow between source electrodes 50 and drain electrode 60. MOSFET 1 operates in this manner.

As described above, in silicon carbide substrate 10 in this embodiment, main surface 13A of each filling portion 13 filling a gap formed between adjacent silicon carbide layers 12 has a surface roughness reduced to not more than 50 μm in RMS value. When forming the epitaxially grown layer on main surface 10A of silicon carbide substrate 10 in this embodiment, therefore, the formation of abnormally grown crystal can be suppressed, thereby suppressing the generation of particles which would be produced by the breakage of such crystal. Thus, silicon carbide substrate 10 in this embodiment is a silicon carbide substrate on which a high quality epitaxially grown layer can be formed. Accordingly, semiconductor layer 20 formed on main surface 10A of silicon carbide substrate 10 is of high quality. Therefore, MOSFET 1 as the semiconductor device in this embodiment including silicon carbide substrate 10 in this embodiment is a high quality semiconductor device.

In silicon carbide substrate 10 in this embodiment, main surface 13A of each filling portion 13 may have a surface roughness of not less than 0.1 μm in RMS value. As a result, cost reduction and productivity improvement in the manufacture of the silicon carbide substrate can be realized while a high quality epitaxially grown layer can be formed.

In order to improve the filling ratio in the gaps between silicon carbide layers 12 and to reduce the surface roughness of filling portions 13, main surface 13A of each filling portion 13 has a surface roughness of preferably not more than 30 μm, more preferably not more than 20 μm, and still more preferably not more than 10 μm, in RMS value. In order to realize cost reduction and productivity improvement in the manufacture of the silicon carbide substrate, main surface 13A of each filling portion 13 has a surface roughness of preferably not less than 0.5 μm, more preferably not less than 1 μm, in RMS value.

In silicon carbide substrate 10 in this embodiment, a main surface 12A of each silicon carbide layer 12 may have a surface roughness of not more than 0.5 nm in RMS value. As a result, a high quality epitaxially grown layer can be formed more readily on main surface 10A of silicon carbide substrate 10. Main surface 12A of each silicon carbide layer 12 more preferably has a surface roughness of not more than 0.3 nm in RMS value. The surface roughness of main surface 12A of each silicon carbide layer 12 can be measured with a stylus roughness meter, a laser displacement meter, a laser microscope, a light interference roughness meter, or an AFM (atomic force microscope), for example.

In silicon carbide substrate 10 in this embodiment, silicon carbide layers 12 may have a dislocation density of not less than 1×10³ cm⁻² and not more than 2×10⁴ cm⁻². As a result, an yield of the semiconductor device including silicon carbide substrate 10 can be increased. Silicon carbide layers 12 more preferably have a dislocation density of not less than 3×10³ cm⁻² and not more than 1×10⁴ cm⁻².

In silicon carbide substrate 10 in this embodiment, silicon carbide layers 12 may have a carrier concentration of not less than 2×10¹⁸ cm⁻³ and not more than 2×10¹⁹ cm⁻³. As a result, a good on-resistance can be achieved in the semiconductor device including silicon carbide substrate 10. Silicon carbide layers 12 more preferably have a carrier concentration of not less than 5×10¹⁸ cm⁻³ and not more than 1×10¹⁹ cm⁻³.

Silicon carbide substrate 10 in this embodiment may have a diameter of not less than 110 mm, more preferably not less than 150 mm. By using such large-diameter silicon carbide substrate, cost reduction and efficiency improvement in the manufacture of the semiconductor device can be realized.

In silicon carbide substrate 10 in this embodiment, each of the plurality of silicon carbide layers 12 may be made of hexagonal silicon carbide. In addition, a surface of each of the plurality of silicon carbide layers 12, which forms main surface 12A opposite to base layer 11, may have an off angle of not less than 0.1 and not more than 10° relative to a {0001} plane. As a result, the epitaxially grown layer can be readily formed on silicon carbide substrate 10.

In silicon carbide substrate 10 in this embodiment, the surface forming main surface 12A of each of the plurality of silicon carbide layers 12 may have an off angle of not more than 4° relative to a {03-38} plane. As a result, a good channel mobility can be achieved in MOSFET 1 including silicon carbide substrate 10. In addition, the surface forming main surface 12A of each of the plurality of silicon carbide layers 12 may have an off angle of not more than 40 relative to a {01-11} plane or a {01-12}plane.

In silicon carbide substrate 10 in this embodiment, the number of metal atoms per 1 cm² present on main surface 10A on which silicon carbide layers 12 are arranged may be not more than 1×10¹⁵. If a metal impurity is present on main surface 10A of silicon carbide substrate 10, epitaxial growth on main surface 10A is inhibited, and the formation of abnormally grown crystal is further facilitated. To address this problem, by setting the number of metal atoms present on main surface 10A of silicon carbide substrate 10 to the above range, the growth of abnormally grown crystal can be suppressed during the epitaxial growth. Consequently, semiconductor layer 20 formed on main surface 10A of silicon carbide substrate 10 is of higher quality, thereby increasing the yield of the semiconductor device including silicon carbide substrate 10.

The number of metal atoms present on main surface 10A of silicon carbide substrate 10 can be measured by extracting the metal with a chemical solution by ICP-MS (inductively coupled plasma mass spectrometry). Here, not only the metal present on a flat portion of main surface 10A but also the metal present in recesses and voids can be extracted and measured. The chemical solution should be able to effectively extract the metal present on main surface 10A, and may be hydrochloric acid, nitric acid, hydrofluoric acid, hydrofluoric-nitric acid, aqua regia or a hydrochloric acid-hydrogen peroxide water mixture, for example.

In order to suppress the abnormal growth during the epitaxial growth on main surface 10A of silicon carbide substrate 10, the number of metal atoms per 1 cm² present on main surface 10A is preferably not more than 1×10¹⁴, more preferably not more than 1×10¹³, still more preferably not more than 1×10¹², and further preferably not more than 1×10¹¹. If the number of metal atoms present on main surface 10A is not more than 5×10⁹, a pronounced effect of suppressing the abnormal growth during the epitaxial growth cannot be achieved. Thus, by setting the number of metals to not less than 5×10⁹, cost reduction and productivity improvement in substrate cleaning can be realized while the abnormal growth can be suppressed during the epitaxial growth.

In silicon carbide substrate 10 in this embodiment, the number of Na atoms per 1 cm² present on main surface 10A on which silicon carbide layers 12 are arranged may be not more than 1×10¹⁴. If Na is present on main surface 10A of silicon carbide substrate 10, the formation of abnormally grown crystal is further facilitated during the epitaxial growth, and the progress of oxidation on main surface 10A is further facilitated. To address this problem, by setting the number of Na atoms present on main surface 10A of silicon carbide substrate 10 to the above range, the growth of abnormally grown crystal can be suppressed during the epitaxial growth, and the progress of oxidation on main surface 10A can be suppressed. Consequently, semiconductor layer 20 formed on main surface 10A of silicon carbide substrate 10 is of higher quality, thereby further increasing the yield of the semiconductor device including silicon carbide substrate 10.

The number of Na atoms per 1 cm² present on main surface 10A of silicon carbide substrate 10 is preferably not more than 1×10¹³, more preferably not more than 1×10¹², still more preferably not more than 1×10¹¹, and further preferably not more than 1×10¹⁰. If the number of Na atoms on main surface 10A is not more than 5×10⁹, a pronounced effect of suppressing the abnormal growth during the epitaxial growth and the progress of oxidation on main surface 10A cannot be achieved. Thus, by setting the number of Na atoms to not less than 5×10⁹, cost reduction and productivity improvement in substrate cleaning can be realized while suppressing the abnormal growth during the epitaxial growth and the progress of oxidation on main surface 10A.

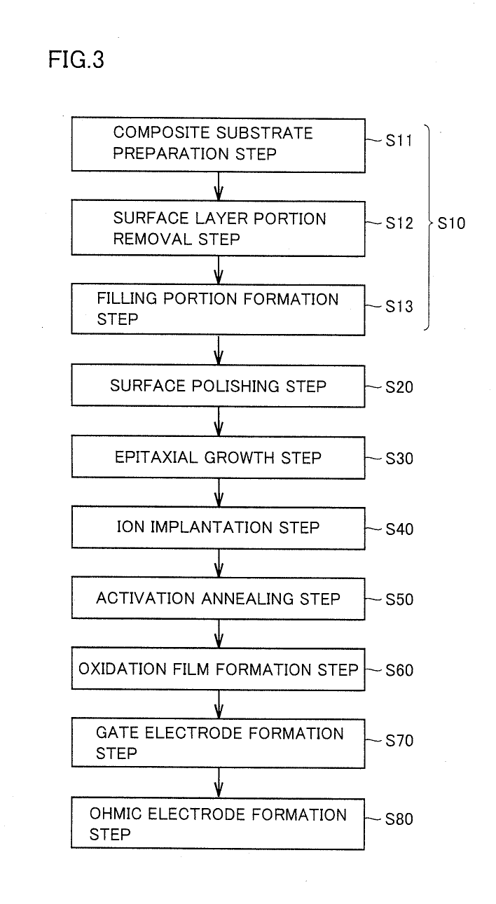

Methods for manufacturing the silicon carbide substrate and the semiconductor device in this embodiment will now be described with reference to FIGS. 3 to 12. With the method for manufacturing the semiconductor device in this embodiment, MOSFET 1 as the semiconductor device in this embodiment can be manufactured.

Referring to FIG. 3, first, in a step (S10), a silicon carbide substrate preparation step is performed. In this step (S10), silicon carbide substrate 10 in this embodiment is prepared by implementing a method for manufacturing a silicon carbide substrate in this embodiment including steps (S11) to (S13) described below.

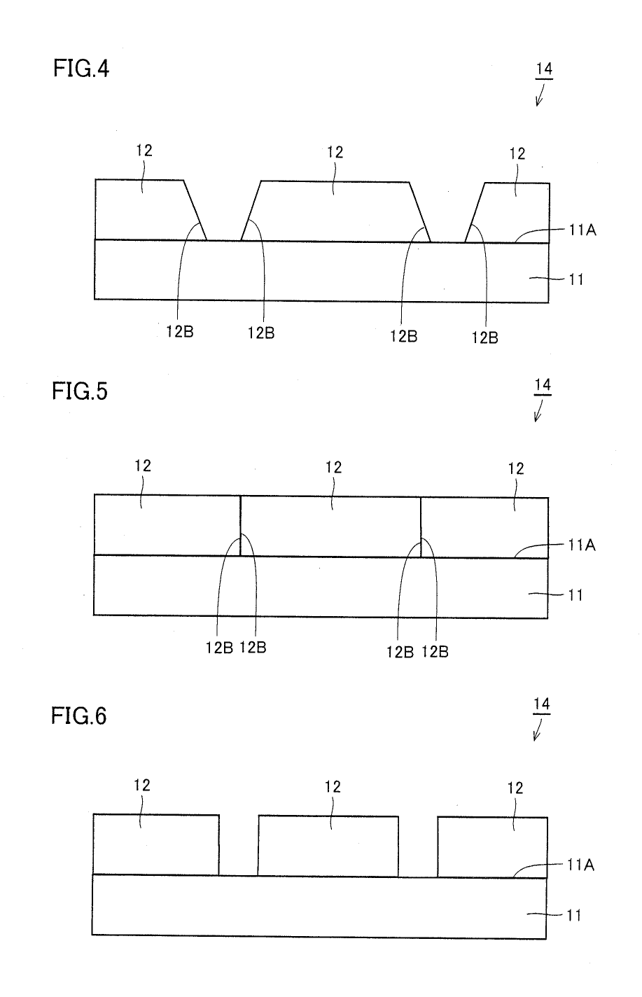

First, in a step (S11), a composite substrate preparation step is performed. In this step (S11), referring to FIG. 4, first, the plurality of SiC substrates 12 made of single-crystal silicon carbide and base substrate 11 made of silicon carbide are prepared. SiC substrates 12 may be subjected to chamfering or the like in advance. The plurality of SiC substrates 12 are then arranged side by side on main surface 11A of base substrate 11 such that gaps are formed between adjacent SiC substrates 12. Then, heating is conducted to a temperature equal to or higher than the sublimation temperature of silicon carbide, for example, to join the plurality of SiC substrates 12 and base substrate 11 to each other. In this manner, a composite substrate 14, in which the plurality of SiC substrates 12 arranged side by side such that gaps are formed between them when viewed in plan view are held on base substrate 11, is prepared.

Alternatively, in this step (S11), composite substrate 14 may be prepared as described below. That is, referring to FIG. 5, first, the plurality of SiC substrates 12 and base substrate 11 are prepared. Then, the plurality of SiC substrates 12 are arranged side by side on main surface 11A of base substrate 11 such that end surfaces 12B of adjacent SiC substrates 12 are in contact with each other. Then, referring to FIG. 6, SiC substrates 12 are partially removed by dicing, for example, in the vicinity of regions where adjacent SiC substrates 12 are in contact with each other, to form gaps between adjacent SiC substrates 12. Composite substrate 14 may be prepared in this manner.

While SiC substrates 12 and base substrate 11 may be joined to each other by close-spaced sublimation as described above in this step (S11), this is not restrictive. SiC substrates 12 and base substrate 11 may be joined to each other using a carbon adhesive, or a SiC adhesive with which SiC is formed by heat treatment, for example.

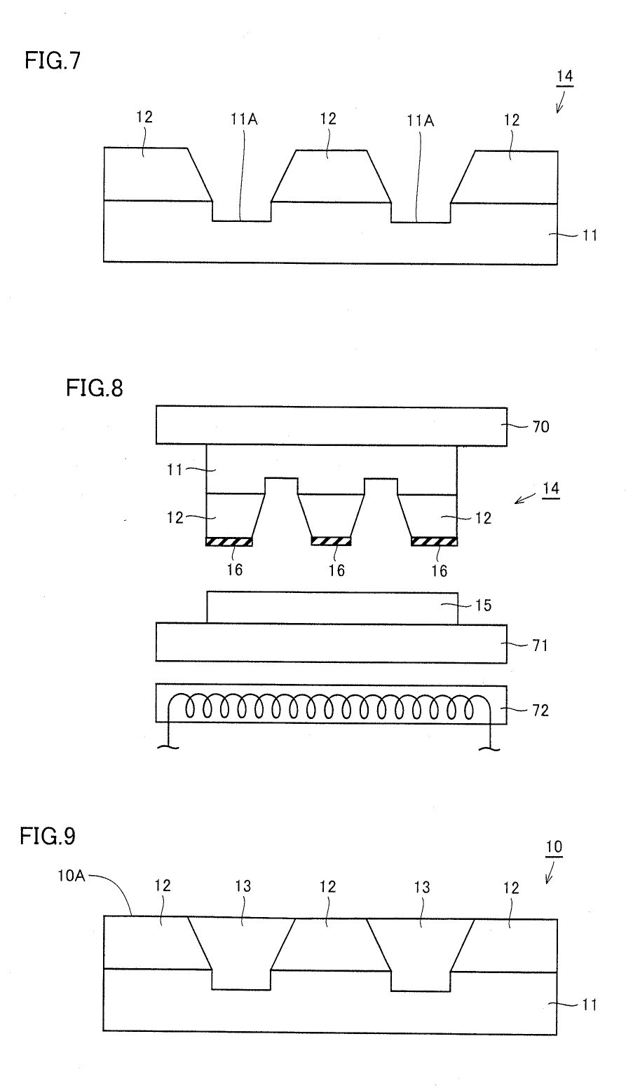

Next, in a step (S12), a surface layer portion removal step is performed. In this step (S12), referring to FIG. 7, surface layer portions of base substrate 11 exposed between adjacent SiC substrates 12 are removed by dicing, polishing and etching, for example. In this step (S12), the surface layer portions of base substrate 11 are removed such that main surface 11A of base substrate 11 exposed between adjacent SiC substrates 12 has a surface roughness of not more than 0.5 μm in RMS value. As a result, when forming filling portions 13 filling the gaps between adjacent SiC substrates 12 in a subsequent step (S13), a reduction in filling ratio in the gaps and a deterioration in surface roughness of filling portions 13 can be suppressed more effectively.

Next, in step (S13), a filling portion formation step is performed. In this step (S13), referring to FIGS. 8 and 9, after the surface layer portions of base substrate 11 were removed in step (S12), filling portions 13 made of silicon carbide are formed to fill the gaps between adjacent SiC substrates 12. More specifically, referring to FIG. 8, first, composite substrate 14 and a source material substrate 15 made of silicon carbide are arranged on a first support member 70 and a second support member 71 arranged to face each other, respectively. Then, mask layers 16 made of carbon, for example, are formed on the main surfaces of SiC substrates 12 facing source material substrate 15. Then, heating to a predetermined temperature is conducted with a heater 72, to sublimate the silicon carbide from a surface of source material substrate 15. The sublimated silicon carbide is deposited to fill the gaps between adjacent SiC substrates 12, to form filling portions 13 made of silicon carbide as shown in FIG. 9.

In this step (S13), a method for forming filling portions 13 is not limited to the sublimation as described above. For example, filling portions 13 made of silicon carbide may be formed by filling the gaps between adjacent SiC substrates 12 with an organic material and performing heat treatment. More specifically, filling portions 13 made of amorphous or polycrystalline silicon carbide may be formed by filling the gaps with an organic material made of Si and C such as polycarbosilane, and performing heat treatment at a temperature between 900° C. and 2100° C.

Moreover, in this step (S13), ultrasonic cleaning may be additionally performed after filling portions 13 were formed. Filling portions 13 have a large surface area because of their projections and depressions, and thus impurities such as metal readily accumulate thereon. By performing the ultrasonic cleaning as described above, therefore, the accumulated impurities can be removed. A chemical solution used in the ultrasonic cleaning may be organic alkali such as choline or TMAH (tetramethylammonium hydroxide), hydrochloric acid, nitric acid, sulfuric acid, hydrofluoric acid, hydrofluoric-nitric acid, aqua regia or a hydrochloric acid-hydrogen peroxide water mixture, for example. The ultrasonic cleaning may be performed in multiple stages by combining a plurality of the chemical solutions above. The accumulated impurities can be removed more effectively by raising the temperature of the chemical solution during the ultrasonic cleaning. By performing steps (S11) to (S13) above, silicon carbide substrate 10 in this embodiment is manufactured, to complete the method for manufacturing the silicon carbide substrate in this embodiment.

Next, in a step (S20), a surface polishing step is performed. In this step (S20), referring to FIG. 9, main surface 10A of silicon carbide substrate 10 is flattened by polishing. As a result, a higher quality epitaxially grown layer can be formed on main surface 10A of silicon carbide substrate 10.

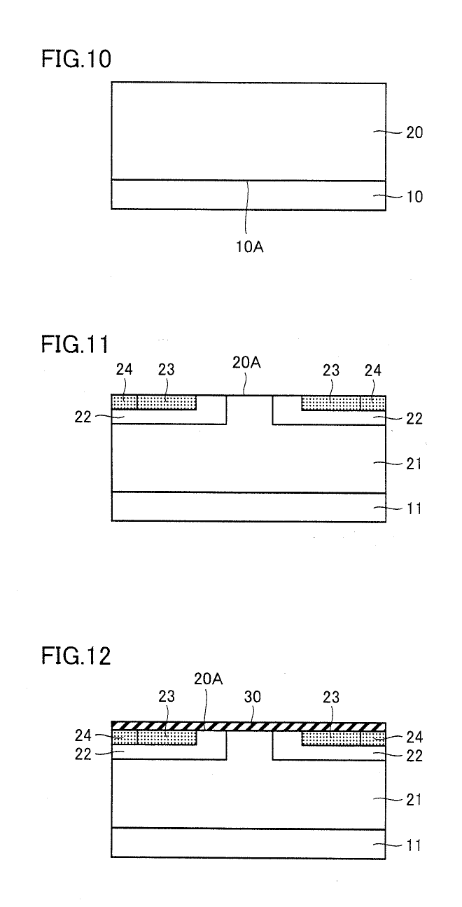

Next, in a step (S30), an epitaxial growth step is performed. In this step (S30), referring to FIG. 10, semiconductor layer 20 made of silicon carbide and having an n conductivity type, for example, is epitaxially grown on main surface 10A of silicon carbide substrate 10.

Next, in a step (S40), an ion implantation step is performed. In this step (S40), referring to FIG. 11, first, Al ions are implanted into regions including main surface 20A of semiconductor layer 20, for example, to form body regions 22. Then, P ions are implanted into the regions including main surface 20A to a depth shallower than the implantation depth of the Al ions, for example, to form source regions 23. Then, Al ions are implanted into regions being adjacent to source regions 23 and including main surface 20A, for example, to form contact regions 24 having the same depth as that of source regions 23. Semiconductor layer 20 includes drift region 21 in an area where body regions 22, source regions 23 and contact regions 24 are not formed.

Next, in a step (S50), an activation annealing step is performed. In this step (S50), silicon carbide substrate 10 on which semiconductor layer 20 including drift region 21, body regions 22, source regions 23 and contact regions 24 is formed is heated to activate the impurities introduced in step (S40). As a result, desired carriers are generated in the regions into which the impurities were introduced.

Next, in a step (S60), an oxidation film formation step is performed. In this step (S60), referring to FIG. 12, silicon carbide substrate 10 having semiconductor layer formed thereon is heated in an atmosphere containing oxygen, for example, to form oxide film 30 made of SiO₂ (silicon dioxide) to cover main surface 20A of semiconductor layer 20.

Next, in a step (S70), a gate electrode formation step is performed. In this step (S70), referring to FIG. 1, gate electrode 40 made of polysilicon is formed on and in contact with oxide film 30 by LPCVD (low pressure chemical vapor deposition).

Next, in a step (S80), an ohmic electrode formation step is performed. In this step (S80), first, oxide film 30 is removed in regions where source electrodes 50 are to be formed, to form regions where source regions 23 and contact regions 24 are exposed. Then, a film made of Ni, for example, is formed in these regions. A film made of Ni, for example, is formed on the main surface of base substrate 11 opposite to the side on which drift region 21 is formed. Then, alloying heat treatment is performed to silicidize at least a part of the film made of Ni, to form source electrodes 50 and drain electrode 60.

In this step (S80), the thickness of substrate 10 may be adjusted before drain electrode 60 is formed. Specifically, base substrate 11 may be removed by grinding or polishing a main surface 10B of substrate 10, and furthermore, the thickness of silicon carbide layers 12 may be reduced. As a result, the on-resistance of MOSFET 1 can be further reduced. If base substrate 11 is removed in this manner, various materials can be employed to form base substrate 11 without regard to effect on device characteristics of MOSFET 1. By performing steps (S10) to (S80) above, MOSFET 1 as the semiconductor device in this embodiment is manufactured, to complete the method for manufacturing the semiconductor device in this embodiment.

As described above, in the method for manufacturing the silicon carbide substrate in this embodiment, before filling portions 13 are formed, the surface roughness of base substrate 11 is reduced by removing the surface layer portions of base substrate 11 exposed between adjacent SiC substrates 12, thereby manufacturing silicon carbide substrate 10 in which a reduction in filling ratio in the gaps between SiC substrates 12, a deterioration in surface roughness of filling portions 13, or the formation of a clearance between SiC substrates 12 and base substrate 11 is suppressed. Accordingly, when forming the epitaxially grown layer on silicon carbide substrate 10, the abnormal crystal growth or the like is suppressed, thereby suppressing the generation of particles that would cause a reduction in quality such as electrical characteristics and durability of the semiconductor device. According to the method for manufacturing the silicon carbide substrate in this embodiment, therefore, silicon carbide substrate 10 on which a high quality epitaxially grown layer can be formed can be manufactured. In addition, according to the method for manufacturing the semiconductor device in this embodiment, silicon carbide substrate 10 manufactured with the method for manufacturing the silicon carbide substrate in this embodiment is prepared. According to the method for manufacturing the semiconductor device in this embodiment, therefore, a high quality semiconductor device can be manufactured.

### Second Embodiment

A silicon carbide substrate, a semiconductor device, and methods for manufacturing them in a second embodiment as another embodiment of the present invention will now be described. The silicon carbide substrate and the semiconductor device in this embodiment basically have the same structures and the same effects as those of the silicon carbide substrate and the semiconductor device in the first embodiment. Furthermore, the methods for manufacturing the silicon carbide substrate and the semiconductor device in this embodiment are basically implemented in the same manner and have the same effects as those of the methods for manufacturing the silicon carbide substrate and the semiconductor device in the first embodiment. However, the method for manufacturing the silicon carbide substrate in this embodiment is different from that in the first embodiment in that a step of forming a cover layer covering the surface of the base substrate is performed instead of the step of removing the surface layer portions of the base substrate exposed between the adjacent SiC substrates.

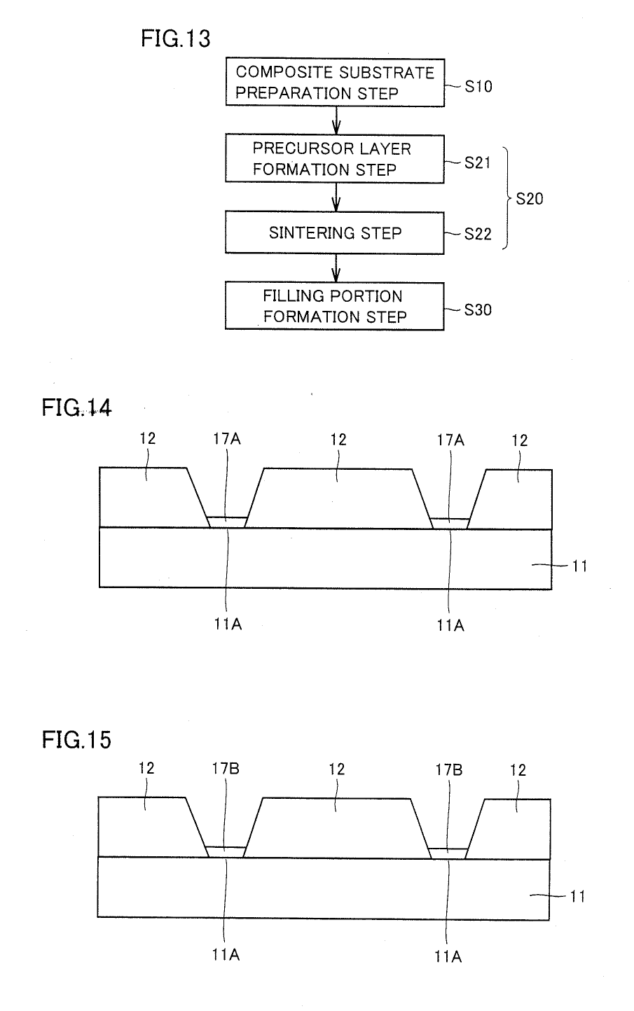

The method for manufacturing the silicon carbide substrate in this embodiment will be described. Referring to FIG. 13, first, in a step (S10), a composite substrate preparation step is performed. In this step (S10), referring to FIG. 4, composite substrate 14, in which the plurality of SiC substrates 12 made of single-crystal silicon carbide and arranged side by side such that gaps are formed between them when viewed in plan view are held on base substrate 11 made of silicon carbide, is prepared in the same manner as the first embodiment.

Next, in a step (S20), a cover layer formation step is performed. In this step (S20), steps (S21) and (S22) described below are performed to form cover layers 17B covering the surface of base substrate 11 exposed between adjacent SiC substrates 12.

First, in a step (S21), a precursor layer formation step is performed. In this step (S21), referring to FIG. 14, an organic material made of Si and C such as polycarbosilane is applied to form precursor layers 17A covering main surface 11A of base layer 11 exposed between adjacent SiC substrates 12. Next, in a step (S22), a sintering step is performed. In this step (S22), referring to FIG. 15, composite substrate 14 is heated to sinter precursor layers 17A, to form cover layers 17B made of silicon carbide. More specifically, the temperature is raised from a low temperature to a temperature of not less than 900° C. and not more than 2100° C. to sinter precursor layers 17A made of polycarbosilane, to form cover layers 17B made of amorphous or polycrystalline silicon carbide. In this step (S22), the generation of cracks caused by volume contraction of the polycarbosilane and the like can be suppressed by raising the temperature to the above range while controlling the rate of temperature rise.

Next, in a step (S30), a filling portion formation step is performed. In this step (S30), referring to FIG. 9, filling portions 13 filling the gaps between adjacent SiC substrates 12 are formed in the same manner as the first embodiment. By performing steps (S10) to (S30) above, silicon carbide substrate 10 in this embodiment is manufactured, to complete the method for manufacturing the silicon carbide substrate in this embodiment.

As described above, in the method for manufacturing the silicon carbide substrate in this embodiment, before filling portions 13 are formed, the surface roughness of base layer 11 is reduced by forming cover layers 17B covering the surface of base substrate 11 exposed between adjacent SiC substrates 12, thereby manufacturing silicon carbide substrate 10 in which a reduction in filling ratio in the gaps between SiC substrates 12 and a deterioration in surface roughness of filling portions 13 are suppressed. Accordingly, when forming the epitaxially grown layer on silicon carbide substrate 10, the abnormal crystal growth or the like caused by a reduction in filling ratio in the gaps between SiC substrates 12 and a deterioration in surface roughness of filling portions 13 is suppressed, thereby suppressing the generation of particles that would cause a reduction in quality such as electrical characteristics and durability of the semiconductor device. According to the method for manufacturing the silicon carbide substrate in this embodiment, therefore, silicon carbide substrate 10 on which a high quality epitaxially grown layer can be formed can be manufactured.

In the method for manufacturing the silicon carbide substrate in this embodiment, in step (S20), cover layers 17B may be formed to have a surface roughness of not more than 0.3 μm in RMS value. As a result, a reduction in filling ratio in the gaps between SiC substrates 12 and a deterioration in surface roughness of filling portions 13 can be suppressed more effectively.

### Third Embodiment

A silicon carbide substrate, a semiconductor device, and methods for manufacturing them in a third embodiment as yet another embodiment of the present invention will now be described. The silicon carbide substrate and the semiconductor device in this embodiment basically have the same structures and the same effects as those of the silicon carbide substrates and the semiconductor devices in the first and second embodiments. Furthermore, the methods for manufacturing the silicon carbide substrate and the semiconductor device in this embodiment are basically implemented in the same manner and have the same effects as those of the methods for manufacturing the silicon carbide substrate and the semiconductor device in the second embodiment. However, the method for manufacturing the silicon carbide substrate in this embodiment is different from that in the second embodiment in the step of forming a cover layer.

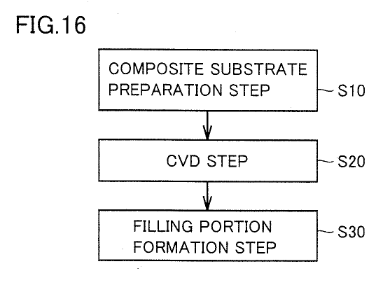

The method for manufacturing the silicon carbide substrate in this embodiment will be described. Referring to FIG. 16, first, in a step (S10), a composite substrate preparation step is performed. In this step (S10), referring to FIG. 4, composite substrate 14, in which the plurality of SiC substrates 12 made of single-crystal silicon carbide and arranged side by side such that gaps are formed between them when viewed in plan view are held on base substrate 11 made of silicon carbide, is prepared in the same manner as the first and second embodiments.

Next, in a step (S20), a CVD (chemical vapor deposition) step is performed. In this step (S20), referring to FIG. 15, composite substrate 14 is subjected to CVD to form cover layers 17B covering main surface 11A of base substrate 11 exposed between adjacent SiC substrates 12. In this manner, by employing CVD, cover layers 17B made of silicon carbide and covering the surface of base substrate 11 exposed between adjacent SiC substrates 12 can be formed more readily.

Next, in a step (S30), a filling portion formation step is performed. In this step (S30), referring to FIG. 9, filling portions 13 filling the gaps between adjacent SiC substrates 12 are formed in the same manner as the first and second embodiments. By performing steps (S10) to (S30) above, silicon carbide substrate 10 in this embodiment is manufactured, to complete the method for manufacturing the silicon carbide substrate in this embodiment.

As described above, in the method for manufacturing the silicon carbide substrate in the first embodiment of the present invention, before filling portions 13 are formed, the surface layer portions of base substrate 11 exposed between adjacent SiC substrates 12 are removed. In the methods for manufacturing the silicon carbide substrates in the second and third embodiments of the present invention, before filling portions 13 are formed, cover layers 17B covering the surface of base substrate 11 exposed between adjacent SiC substrates 12 are formed. In this manner, according to the methods for manufacturing the silicon carbide substrates in the embodiments of the present invention, before filling portions 13 are formed, the surface roughness of main surface 11A of base substrate 11 exposed between adjacent SiC substrates 12 is reduced, thereby manufacturing silicon carbide substrate 10 in which a reduction in filling ratio in the gaps between adjacent SiC substrates 12 and a deterioration in surface roughness of filling portions 13 are suppressed. Accordingly, when forming the epitaxially grown layer on silicon carbide substrate 10, the abnormal crystal growth or the like caused by a reduction in filling ratio in the gaps between SiC substrates 12 and a deterioration in surface roughness of filling portions 13 is suppressed, thereby suppressing the generation of particles that would cause a reduction in quality such as electrical characteristics and durability of the semiconductor device. According to the methods for manufacturing the silicon carbide substrates in the embodiments of the present invention, therefore, silicon carbide substrate 10 on which a high quality epitaxially grown layer can be formed can be manufactured. In addition, according to the methods for manufacturing the semiconductor devices in the embodiments of the present invention, silicon carbide substrate 10 on which a high quality epitaxially grown layer can be formed, which is manufactured with the methods for manufacturing the silicon carbide substrates in the embodiments of the present invention, is prepared. According to the methods for manufacturing the semiconductor devices in the embodiments of the present invention, therefore, high quality MOSFET 1 can be manufactured.

### Example 1

Experiments were conducted to examine relation between the surface roughness of filling portions (joints) in a silicon carbide substrate, the frequency of occurrence of abnormal crystal growth when an epitaxially grown layer was formed on the silicon carbide substrate, and a yield of a semiconductor device manufactured using the silicon carbide substrate. First, silicon carbide substrates each having the same structure as that of silicon carbide substrate 10 in the first embodiment of the present invention described with reference to FIG. 2 were prepared. Specifically, first, composite substrates, in which a plurality of SiC substrates arranged side by side such that gaps are formed between them when viewed in plan view were held on a base substrate, were prepared. Then, joints filling the gaps were formed by filling the gaps between the SiC substrates by sublimation, or by filling the gaps with polycarbosilane and performing heat treatment at 1500° C. The joints were formed to have a surface roughness of 0.05 μm, 0.1 μm, 1 μm, 5 μm, 20 μm, 50 μm and 70 μm, respectively, in RMS value. Then, an epitaxially grown layer was formed on each of the silicon carbide substrates, and the frequency of occurrence of abnormal crystal growth was determined. Furthermore, semiconductor devices were manufactured using the respective silicon carbide substrates, and the yields of the devices were determined. Table 1 shows the frequency of occurrence of abnormal crystal growth, and an effect of surface roughness of the joints in the silicon carbide substrate on the yield of the semiconductor device.

TABLE 1

| | | | | | | | |
|---|---|---|---|---|---|---|---|
| Roughness of | 0.05 | 0.1 | 1 | 5 | 20 | 50 | 70 |
| Joints (μm) | | | | | | | |
| Crystal | — | — | — | Low in | Medium in | High in | High in |
| Growth in | | | | Normal | Normal | Normal | Needle-like |
| Joints | | | | Crystals | Crystals | Crystals | Crystals |
| Device Yield | 80 | 81 | 74 | 68 | 61 | 55 | 20 |
| (%) | | | | | | | |

The experimental results above will be described. As is clear from Table 1, a large number of abnormally grown needle-like crystals were recognized when the joints in the silicon carbide substrate had a surface roughness of 70 μm, whereas the frequency of occurrence of abnormal crystal growth decreased when the joints had a surface roughness of not more than 50 μm. The yield of the semiconductor device improved as the frequency of occurrence of abnormal crystal growth decreased. When the joints had a surface roughness of 0.05 μm, improvement in yield was not recognized as compared to that when the joints had a surface roughness of 0.1 μm. These experimental results were the same when the joints were formed by sublimation, and when the joints were formed by filling the gaps between the SiC substrates with polycarbosilane and performing heat treatment at 1500° C.

It was thus confirmed that, by setting the surface roughness of the joints to not more than 50 μm in the silicon carbide substrate of the present invention, a high quality epitaxially grown layer with low frequency of occurrence of abnormal crystal growth could be formed. It was also confirmed that, when the joints had a surface roughness of not more than 0.1 μm in the silicon carbide substrate of the present invention, a pronounced effect of reduced surface roughness of the joints on the yield of the semiconductor device including the silicon carbide substrate could not be obtained.

### Example 2

Experiments were conducted to examine relation between the amount of metal present on a main surface of a silicon carbide substrate, the frequency of occurrence of abnormal crystal growth when an epitaxially grown layer was formed on the silicon carbide substrate, and a yield of a semiconductor device manufactured using the silicon carbide substrate. First, silicon carbide substrates were prepared in the same manner as Example 1. Then, the prepared silicon carbide substrates were subjected to ultrasonic cleaning, to fabricate silicon carbide substrates each having a predetermined amount of metal on its main surface. The ultrasonic cleaning was performed using ultrapure water and a chemical solution in a clean environment. Then, an epitaxially grown layer was formed on each of the silicon carbide substrates, and the frequency of occurrence of abnormal crystal growth was determined. Furthermore, semiconductor devices were manufactured using the respective silicon carbide substrates, and the yields of the devices were determined. Table 2 shows the frequency of occurrence of abnormal crystal growth, and an effect of the amount of metal present on the main surface of the silicon carbide substrate on the yield of the semiconductor device.

TABLE 2

| | | | | | | | | | |
|---|---|---|---|---|---|---|---|---|---|
| Roughness | 5 | 5 | 5 | 45 | 45 | 45 | 45 | 45 | 45 |
| of Joints | | | | | | | | | |
| (μm) | | | | | | | | | |
| Number of | 3 × 10⁹ | 5 × 10⁹ | 1 × 10¹⁵ | 1 × 10¹¹ | 1 × 10¹² | 1 × 10¹³ | 1 × 10¹⁴ | 1 × 10¹⁵ | 3 × 10¹⁵ |
| Metal Atoms | | | | | | | | | |
| (crn⁻²) | | | | | | | | | |
| Number of | 3 × 10⁹ | 5 × 10⁹ | 1 × 10¹⁴ | l × 10¹⁰ | 1 × 10¹¹ | 1 × 10¹² | 1 × 10¹³ | 1 × 10¹⁴ | 5 × 10¹⁴ |
| Na Atoms | | | | | | | | | |
| (cm⁻²) | | | | | | | | | |
| Crystal | — | — | Low in | — | — | Very | Low in | Medium | High in |
| Growth in | | | Normal | | | Low in | Normal | in | Normal |
| Joints | | | Crystals | | | Normal | Crystals | Normal | Crystals |
| | | | | | | Crystals | | Crystals | |
| Device | 83 | 84 | 69 | 77 | 75 | 71 | 67 | 60 | 53 |
| Yield | | | | | | | | | |
| (%) | | | | | | | | | |

The experimental results above will be described. As is clear from Table 2, the frequency of occurrence of abnormal crystal growth decreased when the number of metal atoms per 1 cm² present on the main surface of the silicon carbide substrate was not more than 1×10¹⁵ and the number of Na atoms was not more than 1×10¹⁴, as compared to when the number of metal atoms was more than 1×10¹⁵ and the number of Na atoms was more than 1×10¹⁴. The yield of the semiconductor device improved as the frequency of occurrence of abnormal crystal growth decreased. It was thus confirmed that, by setting the surface roughness of the joints to not more than 50 μm, and further by setting the number of metal atoms per 1 cm² present on the main surface to not more than 1×10¹⁵ and the number of Na atoms to not more than 1×10¹⁴ in the silicon carbide substrate of the present invention, a high quality epitaxially grown layer with low frequency of occurrence of abnormal crystal growth could be formed more readily. It was also confirmed that, since a high quality epitaxially grown layer could be formed more readily in this manner, the yield of the semiconductor device including the silicon carbide substrate improved.

The silicon carbide substrate, the semiconductor device, and the methods for manufacturing them according to the present invention can be applied particularly advantageously to a silicon carbide substrate required to manufacture a high quality semiconductor device, the semiconductor device, and methods for manufacturing them.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A silicon carbide substrate comprising:
a base layer made of silicon carbide;
silicon carbide layers made of single-crystal silicon carbide and arranged side by side on said base layer when viewed in plan view; and
a filling portion made of silicon carbide and filling a gap formed between adjacent said silicon carbide layers,
said filling portion having a surface roughness of not more than 50 μm in RMS value.

2. The silicon carbide substrate according to claim 1, wherein
said filling portion has a surface roughness of not less than 0.1 μm in RMS value.

3. The silicon carbide substrate according to claim 1, wherein
said silicon carbide layers have a surface roughness of not more than 0.5 nm in RMS value.

4. The silicon carbide substrate according to claim 1, wherein
said silicon carbide layers have a dislocation density of not less than 1×10³ cm⁻² and not more than 2×10⁴ cm⁻².

5. The silicon carbide substrate according to claim 1, wherein
said silicon carbide layers have a carrier concentration of not less than 2×10¹⁸ cm⁻³ and not more than 2×10¹⁹ cm⁻³.

6. The silicon carbide substrate according to claim 1, having a diameter of not less than 110 mm.

7. The silicon carbide substrate according to claim 1, wherein
each of said plurality of silicon carbide layers is made of hexagonal silicon carbide, and
a surface of each of said plurality of silicon carbide layers, which forms a main surface opposite to said base layer, has an off angle of not less than 0.1° and not more than 10° relative to a {0001} plane.

8. The silicon carbide substrate according to claim 1, wherein
each of said plurality of silicon carbide layers is made of hexagonal silicon carbide, and
a surface of each of said plurality of silicon carbide layers, which forms a main surface opposite to said base layer, has an off angle of not more than 4° relative to a {03-38} plane.

9. The silicon carbide substrate according to claim 1, wherein
the number of metal atoms per 1 cm² present on a main surface on which said silicon carbide layers are arranged is not more than 1×10¹⁵.

10. The silicon carbide substrate according to claim 9, wherein
the number of Na atoms per 1 cm² present on said main surface on which said silicon carbide layers are arranged is not more than 1×10¹⁴.

11. A semiconductor device comprising:
a substrate; and
an electrode formed on said substrate,
said substrate being the silicon carbide substrate according to claim 1.

12. The semiconductor device according to claim 11, further comprising an epitaxially grown layer formed on said substrate, wherein
said electrode is formed on said epitaxially grown layer.

13. A method for manufacturing a silicon carbide substrate, comprising the steps of:
preparing a composite substrate, in which a plurality of silicon carbide layers made of single-crystal silicon carbide and arranged side by side when viewed in plan view are held on a base layer made of silicon carbide;
removing a surface layer portion of said base layer exposed between adjacent said silicon carbide layers; and
after said step of removing a surface layer portion of said base layer, forming a filling portion made of silicon carbide and filling a gap between adjacent said silicon carbide layers.

14. The method for manufacturing a silicon carbide substrate according to claim 13, wherein
in said step of removing a surface layer portion of said base layer, the surface layer portion of said base layer is removed such that said base layer exposed between adjacent said silicon carbide layers has a surface roughness of not more than 0.5 μm in RMS value.

15. A method for manufacturing a silicon carbide substrate, comprising the steps of:
preparing a composite substrate, in which a plurality of silicon carbide layers made of single-crystal silicon carbide and arranged side by side when viewed in plan view are held on a base layer made of silicon carbide;
forming a cover layer covering a surface of said base layer exposed between adjacent said silicon carbide layers; and
after said step of forming a cover layer covering a surface of said base layer, forming a filling portion made of silicon carbide and filling a gap between adjacent said silicon carbide layers.

16. The method for manufacturing a silicon carbide substrate according to claim 15, wherein
in said step of forming a cover layer, said cover layer made of silicon carbide is formed.

17. The method for manufacturing a silicon carbide substrate according to claim 16, wherein
in said step of forming a cover layer, said cover layer made of amorphous or polycrystalline silicon carbide is formed.

18. The method for manufacturing a silicon carbide substrate according to claim 16, wherein
said step of forming a cover layer includes the steps of
forming a precursor layer including an organic material made of Si and C and covering the surface of said base layer exposed between adjacent said silicon carbide layers, and
forming said cover layer made of silicon carbide by sintering said precursor layer.

19. The method for manufacturing a silicon carbide substrate according to claim 16, wherein
in said step of forming a cover layer, said cover layer is formed by CVD.

20. The method for manufacturing a silicon carbide substrate according to claim 15, wherein
in said step of forming a cover layer, said cover layer is formed to have a surface roughness of not more than 0.3 μm in RMS value.

21. A method for manufacturing a semiconductor device, comprising the steps of:
preparing a substrate; and
forming an electrode on said substrate,
in said step of preparing a substrate, the silicon carbide substrate manufactured with the method for manufacturing a silicon carbide substrate according to claim 13 being prepared.

22. A method for manufacturing a semiconductor device, comprising the steps of:
preparing a substrate; and
forming an electrode on said substrate,
in said step of preparing a substrate, the silicon carbide substrate according to claim 1 being prepared.

23. The method for manufacturing a semiconductor device according to claim 21, further comprising the step of forming an epitaxially grown layer on said substrate, wherein
in said step of forming an electrode, said electrode is formed on said epitaxially grown layer.
